(19) United States
(12) Patent Application Publication
(10) Pub. No.: US 2025/0323016 A1
(43) Pub. Date: Oct. 16, 2025

(54) MULTIPLE CHARGED PARTICLE BEAM WRITING METHOD, MULTIPLE CHARGED PARTICLE BEAM WRITING APPARATUS, AND STORAGE MEDIUM

(71) Applicant: NuFlare Technology, Inc., Yokohama-shi (JP)

(72) Inventor: Jumpei YASUDA, Kamakura-shi (JP)

(73) Assignee: NuFlare Technology, Inc., Yokohama-shi (JP)

(21) Appl. No.: 19/066,310

(22) Filed: Feb. 28, 2025

(30) Foreign Application Priority Data
Apr. 11, 2024 (JP) 2024-063698

(51) Int. Cl. H01J 37/317; H01J 37/304

(52) U.S. Cl. CPC H01J 37/3177; H01J 37/3045; H01J 2237/0435; H01J 2237/31764; H01J 2237/31776

(57) ABSTRACT

A multiple charged particle beam writing method includes setting a plurality of groups each composed of a plurality of beam irradiation unit regions located in each of a plurality of pitch cell regions being a mesh shape obtained by dividing a writing region of a substrate by a beam pitch size between beams of multiple charged particle beams on the substrate, setting the writing order of each of the plurality of groups each designated by each processing number indicating a processing order of multiple writing processing such that the writing order of each of the plurality of groups is different from each other depending on each processing number, and performing multiple writing in accordance with a set writing order of each of the plurality of groups each designated by each processing number in the multiple writing processing.

### CROSS-REFERENCE TO RELATED APPLICATION

This application is based upon and claims the benefit of priority from prior Japanese Patent Application No. 2024-063698 filed on Apr. 11, 2024 in Japan, the entire contents of which are incorporated herein by reference.

### BACKGROUND OF THE INVENTION

### Field of the Invention

Embodiments of the present invention relate to a multiple charged particle beam writing method, a multiple charged particle beam writing apparatus, and a non-transitory computer-readable storage medium storing a program thereon. For example, embodiments relate to a method for correcting position deviation due to distortion of a beam array occurring on the substrate surface of a multiple beam writing apparatus.

### Description of Related Art

The lithography technique which advances miniaturization of semiconductor devices is extremely important as a unique process whereby patterns are formed in semiconductor manufacturing. In recent years, with high integration of LSI, the line width (critical dimension) necessary for semiconductor device circuits is becoming increasingly narrower year by year. The electron beam writing technique, which intrinsically has excellent resolution, is used for writing or “drawing” patterns on a wafer and the like with electron beams.

For example, as a known example of employing the electron beam writing technique, there is a writing apparatus using multiple beams. Since writing with multiple beams can apply a lot of beams at a time, the writing throughput can be greatly increased compared to writing with a single electron beam. For example, a writing apparatus employing the multiple beam system forms multiple beams by letting an electron beam emitted from an electron gun pass through a mask having a plurality of holes, performs blanking control for each beam, reduces each unblocked beam to generate a reduced mask image by an optical system, and deflects, by a deflector, a reduced beam to be applied to a desired position on a target object or “sample”.

In multiple beam writing, distortion of a beam array shape affects the position accuracy and dimension accuracy of a pattern to be written. To cope with this problem, the number of passes is increased by repeatedly moving the stage while shifting the irradiation region in the y direction at each completion of writing to a stripe region in order to perform multiple writing in the same stripe region, thereby enhancing the averaging effect. However, there is a limit in decreasing distortion of beam array shapes. Furthermore, in the multiple writing performed while repeatedly moving in a stripe region, since the same position is written repeatedly by the same beam or comparatively closer beams, it poses a problem that the effect of reducing the influence due to beam array shape distortion is not sufficiently acquired.

There is disclosed a method for reducing the influence due to distortion of a beam array shape by applying each beam of the first pass according to the first shot order, and, after completing the first pass, applying each beam of the second pass performed while making the stage move in a reverse direction according to the second shot order being different from the first shot order per pixel (e.g., refer to Japanese Patent Application Laid-open (JP-A) No. 2023-042359).

### BRIEF SUMMARY OF THE INVENTION

According to one aspect of the present invention, a multiple charged particle beam writing method includes
setting a plurality of groups each composed of a plurality of beam irradiation unit regions located in each of a plurality of pitch cell regions being a mesh shape obtained by dividing a writing region of a substrate by a beam pitch size between beams of multiple charged particle beams on the substrate,
setting a writing order of each of the plurality of groups each designated by each processing number indicating a processing order of multiple writing processing such that the writing order of the each of the plurality of groups is different from each other depending on the each processing number, and
performing multiple writing in accordance with a set writing order of the each of the plurality of groups each designated by the each processing number in the multiple writing processing.

According to another aspect of the present invention, a non-transitory computer-readable storage medium storing a program for causing a computer to execute processing includes
setting a plurality of groups each composed of a plurality of beam irradiation unit regions located in each of a plurality of pitch cell regions being a mesh shape obtained by dividing a writing region of a substrate by a beam pitch size between beams of multiple charged particle beams on the substrate,
setting a writing order of each of the plurality of groups each designated by each processing number indicating a processing order of multiple writing processing such that the writing order of the each of the plurality of groups is different from each other depending on the each processing number,
storing, in a storage device, a set writing order of the each of the plurality of groups each designated by the each processing number in the multiple writing processing, and
reading the set writing order of the each of the plurality of groups each designated by the each processing number in the multiple writing processing from the storage device, and performing multiple writing in accordance with the set writing order of the each of the plurality of groups each designated by the each processing number in the multiple writing processing.

According to yet another aspect of the present invention, a multiple charged particle beam writing apparatus includes
a group setting circuit configured to set a plurality of groups each composed of a plurality of beam irradiation unit regions located in each of a plurality of pitch cell regions being a mesh shape obtained by dividing a writing region of a substrate by a beam pitch size between beams of multiple charged particle beams on the substrate,
a group order setting circuit configured to set a writing order of each of the plurality of groups each designated by each processing number indicating a processing order of multiple writing processing such that the writing order of the each of the plurality of groups is different from each other depending on the each processing number, and
a writing control circuit configured to perform multiple writing in accordance with a set writing order of the each of the plurality of groups each designated by the each processing number in the multiple writing processing.

According to yet another aspect of the present invention, a multiple charged particle beam writing method includes
setting a writing order of a plurality of beam irradiation unit regions in each of a plurality of pitch cell regions each designated by each processing number indicating a processing order of multiple writing processing, where the plurality of pitch cell regions have been obtained by dividing, to be a mesh shape, a writing region of a substrate by a beam pitch size between beams of multiple charged particle beams on the substrate such that the writing order of the plurality of beam irradiation unit regions in the each of the plurality of pitch cell regions is different from each other depending on the each processing number, and
performing multiple writing, in each tracking cycle of repeating a tracking control that makes an irradiation region of the multiple charged particle beams follow a movement of the substrate placed on a stage moving continuously and a tracking reset that resets a position of the irradiation region of the multiple charged particle beams, while performing writing processing indicated by a processing number concerned having been sequentially changed in the multiple writing processing, in accordance with a set writing order of the plurality of beam irradiation unit regions in the each of the plurality of pitch cell regions each designated by the each processing number in the multiple writing processing during one movement of the stage in a direction parallel to a writing direction, by writing, with each beam of the multiple charged particle beams, a same beam irradiation unit region in any one of the plurality of pitch cell regions being different from each other in the irradiation region of the multiple charged particle beams during the tracking control performed in the writing processing indicated by the processing number concerned.

### BRIEF DESCRIPTION OF THE DRAWINGS

FIG. 1 is an illustration showing a schematic diagram of a configuration of a writing apparatus according to a first embodiment;

FIG. 2 is a conceptual diagram showing a configuration of a shaping aperture array substrate according to the first embodiment;

FIG. 3 is a sectional view showing a configuration of a blanking aperture array mechanism according to the first embodiment;

FIG. 4 is a conceptual diagram showing an example of writing operations according to the first embodiment;

FIG. 5 is an illustration showing an example of an irradiation region of multiple beams and a writing target pixel according to the first embodiment;

FIG. 6 is a flowchart showing an example of main steps of a writing method according to the first embodiment;

FIG. 7 is an illustration showing an example of a sub-irradiation region and an example of groups according to the first embodiment;

FIG. 8 is an illustration explaining a part of an example of a multiple beam writing operation according to the first embodiment;

FIG. 9 is an illustration explaining a part of another example of a multiple beam writing operation according to the first embodiment;

FIG. 10 is an illustration showing an example of numbers of beams having written a sub-irradiation region according to the first embodiment;

FIG. 11 is an illustration showing an example of an average beam number of a plurality of beams which write respective positions according to the first embodiment and a comparative example 1;

FIG. 12 is an illustration showing an example of a relationship between a position deviation amount and a pixel position, in writing processing indicated by each processing number in multiple writing processing according to the first embodiment;

FIG. 13 is an illustration showing an example of a relationship between a position deviation amount and a pixel position, in writing processing indicated by each processing number in multiple writing processing according to the comparative example 1 of the first embodiment;

FIG. 14 is an illustration showing an example of a relationship between a position deviation amount and a pixel position, in writing processing indicated by each processing number in multiple writing processing according to a comparative example 2 of the first embodiment;

FIG. 15 is an illustration showing an example of a relation between an average error value and a pixel position in multiple writing processing to a pixel at the same position in each sub-irradiation region according to the first embodiment;

FIG. 16 is an illustration showing an example of a relation between an average error value and a pixel position in multiple writing processing to a pixel at the same position in each sub-irradiation region according to the comparative example 1 of the first embodiment;

FIG. 17 is an illustration showing an example of a relation between an average error value and a pixel position in multiple writing processing to a pixel at the same position in each sub-irradiation region according to the comparative example 2 of the first embodiment;

FIG. 18 is a flowchart showing an example of main steps of a writing method according to a second embodiment;

FIG. 19 is an illustration explaining a part of an example of a multiple beam writing operation according to the second embodiment; and

FIG. 20 is an illustration explaining a part of another example of a multiple beam writing operation according to the second embodiment.

### DETAILED DESCRIPTION OF THE INVENTION

Embodiments below provide a method by which position deviation of a pattern due to distortion of a beam array shape can be reduced.

Embodiments below describe a configuration in which an electron beam is used as an example of a charged particle beam. The charged particle beam is not limited to the electron beam, and other charged particle beams such as an ion beam may also be used.

### First Embodiment

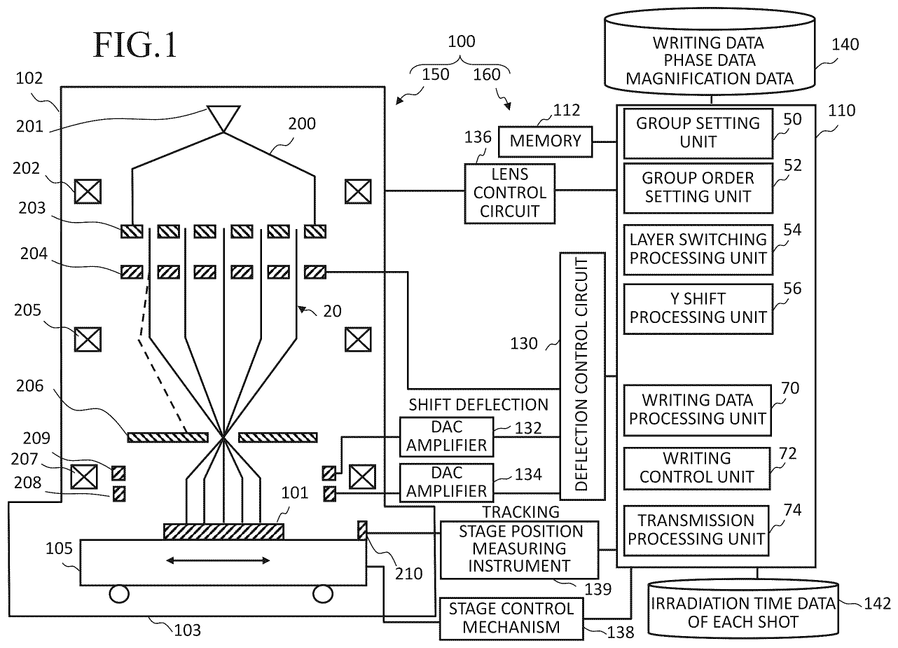

FIG. 1 is an illustration showing a schematic diagram of a configuration of a writing or “drawing” apparatus according to a first embodiment. As shown in FIG. 1, a writing apparatus 100 includes a writing mechanism 150 and a control system circuit 160. The writing apparatus 100 is an example of a multiple charged particle beam writing apparatus and a multiple charged particle beam exposure apparatus. The writing mechanism 150 includes an electron optical column 102 (electron beam column) and a writing chamber 103. In the electron optical column 102, there are disposed an electron gun 201, an illumination lens 202, a shaping aperture array substrate 203, a blanking aperture array mechanism 204, a reducing lens 205, a limiting aperture substrate 206, an objective lens 207, a main deflector 208, and a sub deflector 209.

In the writing chamber 103, an XY stage 105 is disposed. On the XY stage 105, there is placed a target object or “sample” 101 such as a mask serving as a writing target substrate when writing (exposure) is performed. The target object 101 is, for example, an exposure mask used in fabricating semiconductor devices, or a semiconductor substrate (silicon wafer) for fabricating semiconductor devices. Furthermore, the target object 101 may be, for example, a mask blank on which resist has been applied and nothing has yet been written. On the XY stage 105, a mirror 210 for measuring the position of the XY stage 105 is placed.

The control system circuit 160 includes a control computer 110, a memory 112, a deflection control circuit 130, digital-analog converter (DAC) amplifier units 132 and 134, a lens control circuit 136, a stage control mechanism 138, a stage position measuring instrument 139, and storage devices 140 and 142 such as magnetic disk drives. The control computer 110, the memory 112, the deflection control circuit 130, the lens control circuit 136, the stage control mechanism 138, the stage position measuring instrument 139, and the storage devices 140 and 142 are connected to each other through a bus (not shown). The DAC amplifier units 132 and 134 and the blanking aperture array mechanism 204 are connected to the deflection control circuit 130. The sub deflector 209 is composed of at least four electrodes (or “at least four poles”), and controlled by the deflection control circuit 130 through the DAC amplifier unit 132 disposed for each electrode. The main deflector 208 is composed of at least four electrodes (or “at least four poles”), and controlled by the deflection control circuit 130 through the DAC amplifier unit 134 disposed for each electrode. Lenses such as the illumination lens 202, the reducing lens 205, and the objective lens 207 are controlled by the lens control circuit 136.

The position of the XY stage 105 is controlled by the drive of each axis motor (not shown) which is controlled by the stage control mechanism 138. Based on the principle of laser interferometry, the stage position measurement instrument 139 measures the position of the XY stage 105 by receiving a reflected light from the mirror 210.

In the control computer 110, there are arranged a group setting unit 50, a group order setting unit 52, a layer switching processing unit 54, a Y shift processing unit 56, a writing data processing unit 70, a writing control unit 72, and a transmission processing unit 74. Each of the “ . . . units” such as the group setting unit 50, the group order setting unit 52, the layer switching processing unit 54, the Y shift processing unit 56, the writing data processing unit 70, the writing control unit 72, and the transmission processing unit 74 includes processing circuitry. The processing circuitry includes, for example, an electric circuit, a computer, a processor, a circuit board, a quantum circuit, a semiconductor device, or the like. Each “ . . . unit” may use common processing circuitry (the same processing circuitry), or different processing circuitry (separate processing circuitry). Information input/output to/from the group setting unit 50, the group order setting unit 52, the layer switching processing unit 54, the Y shift processing unit 56, the writing data processing unit 70, the writing control unit 72, and the transmission processing unit 74, and information being operated are stored in the memory 112 each time.

Writing operations of the writing apparatus 100 are controlled by the writing control unit 72. In other words, the writing control unit 72 (an example of a control circuit) controls the writing mechanism 150. Processing of transmitting irradiation time data of each shot to the deflection control circuit 130 is controlled by the transmission control unit 74.

Writing data (chip data) is input from the outside of the writing apparatus 100, and stored in the storage device 140. Chip data defines information on a plurality of figure patterns configuring a chip pattern. Specifically, for example, coordinates for each vertex are defined for each figure pattern in the order of configuration of the figure. Alternatively, for example, a figure code, coordinates, a size, and the like are defined for each figure pattern.

FIG. 1 shows a configuration necessary for describing the first embodiment. Other configuration elements generally necessary for the writing apparatus 100 may also be included therein.

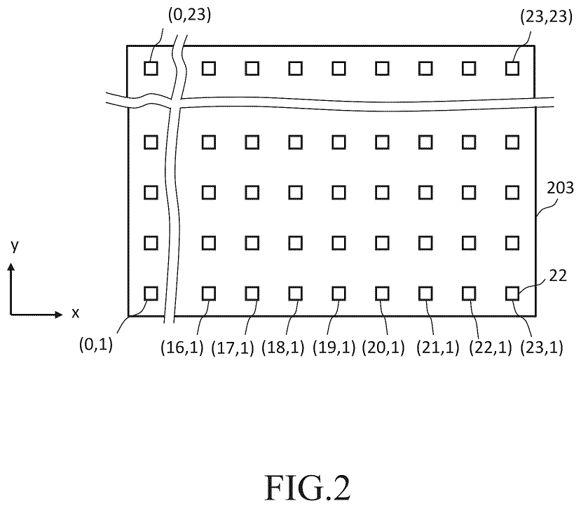

FIG. 2 is a conceptual diagram showing a configuration of a shaping aperture array substrate according to the first embodiment. As shown in FIG. 2, holes (openings) 22 of p rows long (length in the y direction) and q columns wide (width in the x direction) (p≥2, q≥2) are formed, like a matrix, at a predetermined arrangement pitch in the shaping aperture array substrate 203. In the case of FIG. 2, for example, holes 22 of 24×24, that is 24 holes in the y direction and 24 holes in the x direction, are formed. The number of holes 22 is not limited thereto. For example, it is also preferable to form the holes 22 of 512×512. Each of the holes 22 is a rectangle (including square) having the same dimension and shape as each other. Alternatively, each of the holes 22 may be a circle with the same diameter as each other. The multiple beams 20 are formed by letting portions of an electron beam 200 individually pass through a corresponding one of a plurality of holes 22. In other words, the shaping aperture array substrate 203 forms the multiple beams 20.

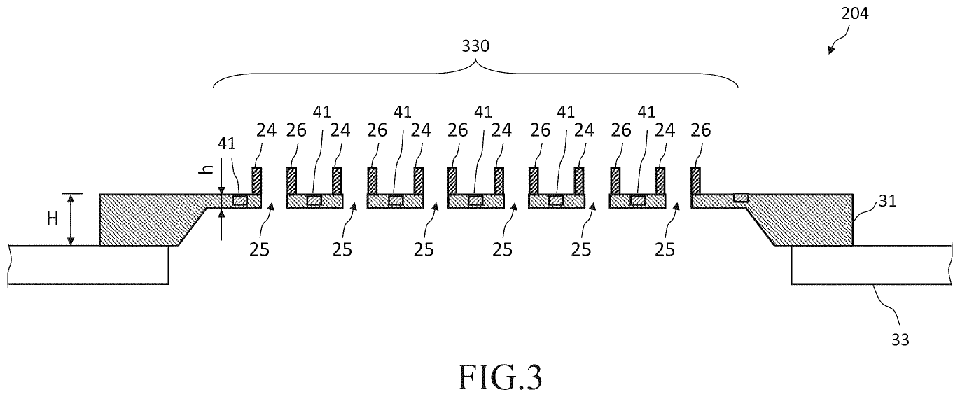

FIG. 3 is a sectional view showing a configuration of a blanking aperture array mechanism according to the first embodiment. In the blanking aperture array mechanism 204, as shown in FIG. 3, a blanking aperture array substrate 31 being a semiconductor substrate made of silicon, etc. is disposed on a support table 33. In a membrane region 330 at the center of the blanking aperture array substrate 31, a plurality of passage holes 25 (openings), through each of which a corresponding one of the multiple beams 20 passes, are formed at positions each corresponding to each hole 22 in the shaping aperture array substrate 203 shown in FIG. 2. A pair of a control electrode 24 and a counter electrode 26, (blanker: blanking deflector), is arranged in a manner such that the electrodes 24 and 26 are opposite to each other across a corresponding one of the plurality of the passage holes 25. A control circuit 41 (logic circuit) which applies a deflection voltage to the control electrode 24 for the passage hole 25 concerned is disposed, inside the blanking aperture array substrate 31, close to each corresponding passage hole 25. The counter electrode 26 for each beam is grounded.

In the control circuit 41, an amplifier (not shown) (an example of a switching circuit) is arranged. As an example of the amplifier, a CMOS (Complementary MOS) inverter circuit serving as a switching circuit is disposed. With regard to inputs (IN) to the CMOS inverter circuit, either an L (low) potential (e.g., ground potential) lower than a threshold voltage, or an H (high) potential (e.g., 1.5 V) higher than or equal to the threshold voltage is applied as a control signal. According to the first embodiment, in a state where an L potential is applied to the input (IN) of the CMOS inverter circuit, the output (OUT) of the CMOS inverter circuit, which is to be applied to the control circuit 41, becomes a positive potential (Vdd), and then, a corresponding beam is deflected by an electric field due to a potential difference from the ground potential of the counter electrode 26, and is controlled to be in a beam OFF condition by being blocked by the limiting aperture substrate 206. In contrast, in a state (active state) where an H potential is applied to the input (IN) of the CMOS inverter circuit, the output (OUT) of the CMOS inverter circuit becomes a ground potential, and therefore, since there is no potential difference from the ground potential of the counter electrode 26, a corresponding beam is not deflected, and is controlled to be in a beam ON condition by passing through the limiting aperture substrate 206. Blanking control is provided by such deflection.

Next, operations of the writing mechanism 150 will be described. The electron beam 200 emitted from the electron gun 201 (emission source) almost perpendicularly (e.g., vertically) illuminates the whole of the shaping aperture array substrate 203 by the illumination lens 202. A plurality of rectangular holes 22 (openings) are formed in the shaping aperture array substrate 203. The region including all of the plurality of holes 22 is irradiated with the electron beam 200. For example, rectangular multiple beams (a plurality of electron beams) 20 are formed by letting portions of the electron beam 200 applied to the positions of the plurality of holes 22 individually pass through a corresponding one of the plurality of holes 22 in the shaping aperture array substrate 203. The multiple beams 20 individually pass through corresponding blankers of the blanking aperture array mechanism 204. The blanker provides blanking control such that a corresponding beam individually passing becomes in an ON condition during a set writing time (irradiation time).

The multiple beams 20 having passed through the blanking aperture array mechanism 204 are reduced by the reducing lens 205, and travel toward the hole in the center of the limiting aperture substrate 206. Then, the electron beam which was deflected by the blanker of the blanking aperture array mechanism 204 deviates from the hole in the center of the limiting aperture substrate 206 and is blocked by the limiting aperture substrate 206. In contrast, the electron beam which was not deflected by the blanker of the blanking aperture array mechanism 204 passes through the hole in the center of the limiting aperture substrate 206 as shown in FIG. 1. Thus, the limiting aperture substrate 206 blocks each beam which was deflected to be in the OFF state by the blanker of the blanking aperture array mechanism 204. Then, each beam for one shot of the multiple beams 20 is formed by a beam which has been made during a period from becoming beam ON to becoming beam OFF and has passed through the limiting aperture substrate 206. The multiple beams 20 having passed through the limiting aperture substrate 206 are focused by the objective lens 207 so as to be a pattern image of a desired reduction ratio. Then, all of the multiple beams 20 having passed through the limiting aperture substrate 206 are collectively deflected in the same direction by the main deflector 208 and the sub deflector 209 in order to irradiate respective beam irradiation positions on the target object 101. For example, when the XY stage 105 is continuously moving, tracking control is performed by the main deflector 208 so that the beam irradiation position may follow the movement of the XY stage 105. Ideally, the multiple beams 20 irradiating at a time are aligned at a pitch obtained by multiplying the arrangement pitch of a plurality of holes 22 in the shaping aperture array substrate 203 by the desired reduction ratio described above.

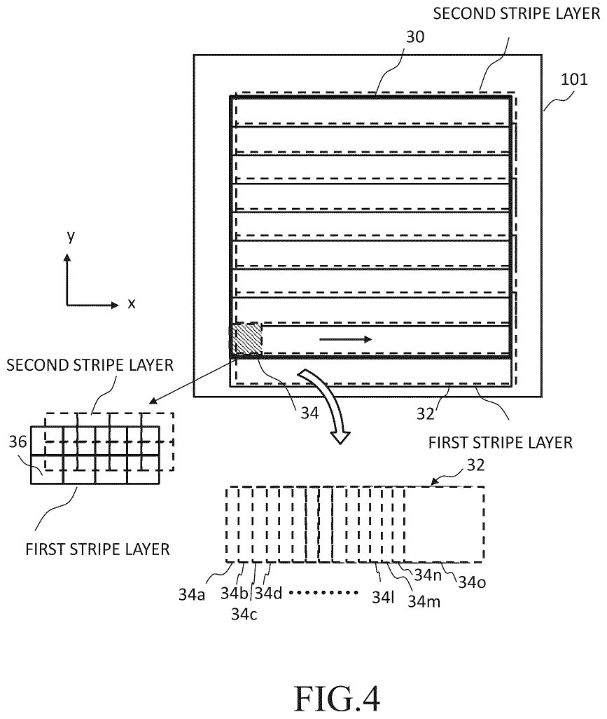

FIG. 4 is a conceptual diagram showing an example of writing operations according to the first embodiment. As shown in FIG. 4, a writing region 30 (bold line) of the target object 101 is virtually divided into a plurality of stripe regions 32 by a predetermined width in the y direction, for example. In the case of FIG. 4, the writing region 30 of the target object 101 is divided in the y direction, for example, into a plurality of stripe regions 32 by the width size being substantially the same as the design size of an irradiation region 34 (writing field) that can be irradiated with one irradiation of the multiple beams 20.

FIG. 4 shows the case of performing multiple writing of multiplicity 2, for example. The first stripe layer composed of a plurality of stripe regions 32 obtained by dividing the writing region 30 is set for the first writing processing whose processing number is “the 1st”, where processing numbers indicate the order of processing of multiple writing processing. Furthermore, the second stripe layer composed of a plurality of stripe regions 32 obtained by shifting the position of the first stripe layer in the y direction by ½ of the pixel size of a pixel 36 to be described later is set for the second writing processing whose processing number in multiple writing processing is “the 2nd”. Thus, in the example of FIG. 4, two stipe layers of the first stripe layer and the second stripe layer are set. Therefore, by combining the first and second stripe layers, a plurality of stripe regions 32 are arranged with partially overlapping with each other in the y direction. FIG. 4 shows the case where the stripe regions 32 adjacent to each other in the y direction are overlapped with each other excluding some portions. It is preferable that one surplus stripe region 32 is set in the −y direction at the end of the writing region 30 in each stripe layer. The multiplicity is not limited two, and may be three or more.

For example, in the case of performing multiple writing of multiplicity 4, the first stripe layer is set for the first writing processing whose processing number in multiple writing processing is “the 1st”, the second stripe layer is set for the second writing processing whose processing number in multiple writing processing is “the 2nd”, the third stripe layer is set for the third writing processing whose processing number in multiple writing processing is “the 3rd”, and the fourth stripe layer is set for the fourth writing processing whose processing number in multiple writing processing is “the 4th”. It is preferable that each stripe layer is shifted from each other in the y direction by ¼ of the pixel size.

The direction of the position deviation less than the pixel size described above is not limited to the y direction. It is also preferable as shown in FIG. 4 to deviate in the x direction. Next, an example of the writing operation will be explained below.

First, the XY stage 105 is moved to make an adjustment such that the irradiation region 34 of the multiple beams 20 is located at the left end, or at a position further left than the left end, of the first stripe region 32 of the first stripe layer. Then, when performing writing to the first stripe region 32, the XY stage 105 is moved, for example, in the −x direction, so that the writing may proceed relatively in the x direction. The XY stage 105 is moved, for example, continuously at a constant speed. According to the first embodiment, during one movement (one pass) in the −x direction of the XY stage 105, all the first stripe regions 32 in each of the stripe layers are written.

After writing to the first stripe region 32 of each stripe layer, the stage position is moved in the −y direction by the width size of the stripe region 32. Thereby, the stripe region 32 to be written is shifted (displaced) in the y direction by the width size of the stripe region 32.

Next, an adjustment is made so that the irradiation region 34 of the multiple beams 20 can be located at the left end, or at a position further left than the left end, of the second stripe region 32 of the first stripe layer. By moving the XY stage 105, for example, in the −x direction, writing proceeds relatively in the x direction. Thereby, writing is performed to the second stripe region 32 of each stripe layer. In this way, during one movement (one pass) in the −x direction of the XY stage 105, all the second stripe regions 32 in each of the stripe layers are written. Henceforth, by repeating similar operations, writing to all the stripe regions 32 in each of the stripe layers is performed. The switching (changing) of the stripe layer in each pass is performed by Y deflection by the main deflector 28 described later. Thereby, multiple writing is performed to the stripe region 32 in each stripe layer.

FIG. 4 shows the case where each stripe region 32 is written in the same direction, but, it is not limited thereto. For example, with respect to the stripe region 32 to be written following the stripe region 32 having already been written in the x direction, it may be written in the −x direction by moving the XY stage 105 in the x direction, for example. Thus, due to performing writing while alternately changing the writing direction, the stage moving time can be reduced, which results in reducing the writing time. Owing to one shot of multiple beams having been formed by individually passing through the holes 22 in the shaping aperture array substrate 203, a plurality of shot patterns maximally up to as many as the number of the holes 22 are formed at a time.

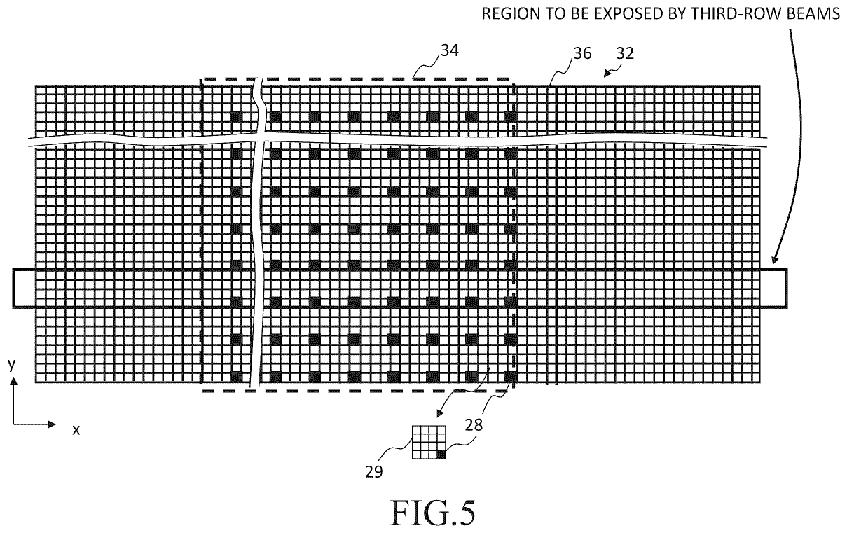

FIG. 5 is an illustration showing an example of an irradiation region of multiple beams and a pixel to be written (writing target pixel) according to the first embodiment. In FIG. 5, the stripe region 32 is divided into a plurality of mesh regions by the beam size of the multiple beams 20, for example. Each mesh region serves as a writing target pixel 36 (beam irradiation unit region, irradiation position). The size of the writing target pixel 36 is not limited to the beam size, and may be any size regardless of beam size. For example, it may be 1/n (n being an integer of 1 or more) of the beam size. FIG. 5 shows the case where the writing region of the target object 101 is divided, for example, in the y direction, into a plurality of stripe regions 32 by the width size being substantially the same as the size of the irradiation region 34 (writing field) that can be irradiated with one irradiation of the multiple beams 20. The x-direction size of the rectangular, including square, irradiation region 34 can be defined by (the number of x-direction beams)×(beam pitch in the x direction). The y-direction size of the rectangular irradiation region 34 can be defined by (the number of y-direction beams)×(beam pitch in the y direction). FIG. 5 shows the case of multiple beams of 24×24 (rows×columns) having been simplified to 8×8 (rows×columns). In the irradiation region 34, there are shown a plurality of pixels 28 (beam writing positions) that can be irradiated with one shot of the multiple beams 20. The pitch between adjacent pixels 28 is the beam pitch of the multiple beams. A sub-irradiation region 29 (pitch cell region) is configured by a rectangular, including square, region surrounded by the size of beam pitches in the x and y directions. In the example of FIG. 5, each sub-irradiation region 29 is composed of 4×4 pixels, for example.

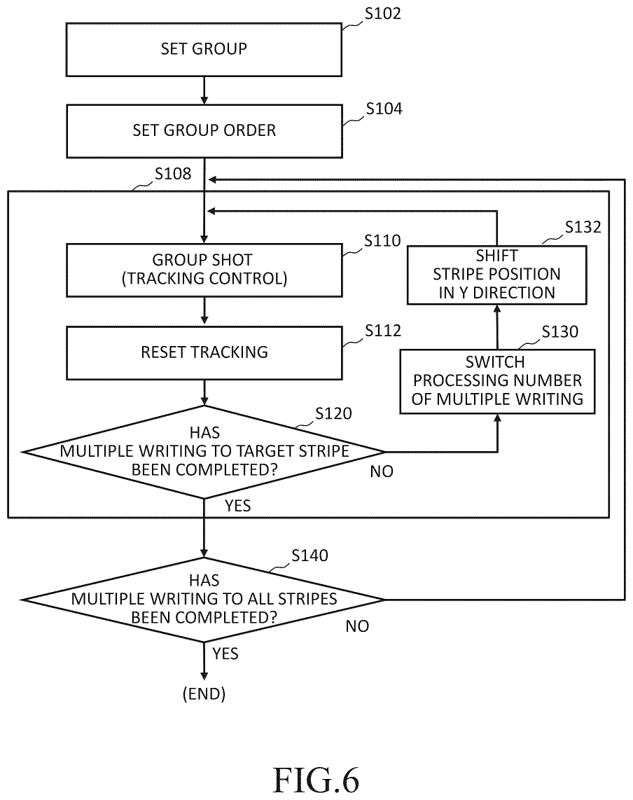

FIG. 6 is a flowchart showing an example of main steps of a writing method according to the first embodiment. In FIG. 6, the writing method of the first embodiment executes a series of steps: a group setting step (S102), a group order setting step (S104), a multiple writing step (S108), and a determining step (S140). The multiple writing step (S108) executes, as internal steps, a group shot (tracking control) step (S110), a tracking reset step (S112), a determining step (S120), a multiple writing processing number switching step (S130), and a stripe position Y shifting step (S132).

In the group setting step (S102), the group setting unit 50 sets a plurality of groups, each of which is composed of a plurality of pixels 36, located in each of a plurality of sub-irradiation regions 29 (pitch cell regions) being a mesh shape obtained by dividing the stripe region 32 (an example of a writing region) of the target object 101 (substrate) by the beam pitch size between beams of the multiple beams 20 on the target object 101.

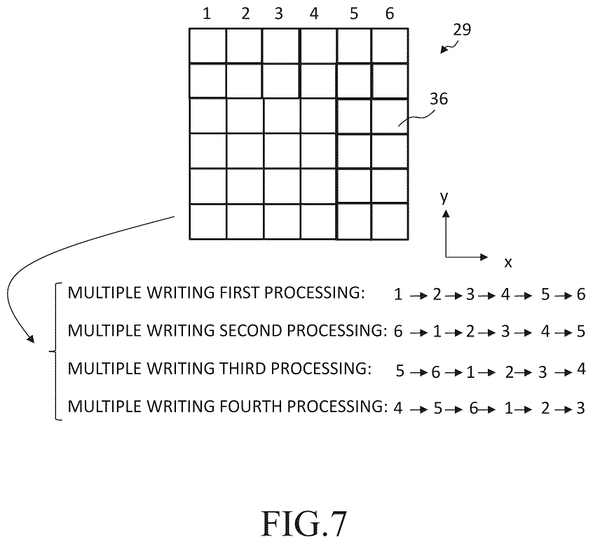

FIG. 7 is an illustration showing an example of the sub-irradiation region and an example of groups according to the first embodiment. FIG. 7 shows the case where each sub-irradiation region 29 is composed of 6×6 pixels 36, for example. In the case of FIG. 7, each group is composed of six pixels arrayed in the y direction, where each of the six pixels configures a pixel row in the x direction. Therefore, the example of FIG. 7 shows six groups from 1 to 6. It is preferable that the number of pixels in each group is the number of pixels being shot during one tracking control.

In the group order setting step (S104), the group order setting unit 52 sets the writing order of each of a plurality of groups each of which is designated by the processing number indicating the processing order of multiple writing processing such that the writing orders of the plurality of groups are different from each other depending on the processing number in the multiple writing processing. That is to say, in the case of performing multiple writing of multiplicity 4, the group order setting unit 52 sets the writing order of each of a plurality of groups in each sub-irradiation region 29 in each stripe region 32 located in each of the first, second, third, and fourth stripe layers so that the writing order of the each of the plurality of groups may be different from each other among the first, second, third, and fourth stripe layers. In that case, it is preferable, with respect to each processing number in multiple writing processing, to sequentially shift the writing order of each of a plurality of groups. In other words, it is preferable to shift the writing cycle of each group in the multiple writing processing.

In the example of FIG. 7, in the multiple writing first processing (that is, the first processing of multiple writing processing) whose processing number is “the 1st”, writing is performed in the order of the groups 1, 2, 3, 4, 5, and 6, for example, in each sub-irradiation region 29. In the multiple writing second processing (that is, the second processing of multiple writing processing) whose processing number is “the 2nd”, writing is performed in the order of the groups 6, 1, 2, 3, 4, and 5, for example, in each sub-irradiation region 29. In the multiple writing third processing (that is, the third processing of multiple writing processing) whose processing number is “the 3rd”, writing is performed in the order of the groups 5, 6, 1, 2, 3, and 4, for example, in each sub-irradiation region 29. In the multiple writing fourth processing (that is, the fourth processing of multiple writing processing) whose processing number is “the 4th”, writing is performed in the order of the groups 4, 5, 6, 1, 2, and 3, for example, in each sub-irradiation region 29.

In the multiple writing step (S108), first, the writing data processing unit 70 reads chip data (writing data) stored in the storage device 140, and generates irradiation time data per pixel, for each writing processing indicated by a processing number in multiple writing processing. For example, in writing processing of multiplicity 4, in each writing processing indicated by a processing number, a beam of ¼ dose of a necessary dose, for example, is applied to a target pixel. Irradiation time data is rearranged in the order of shots in accordance with a preset writing sequence. The irradiation time data is stored in the storage device 142. The transmission processing unit 74 transmits the irradiation time data in the order of shots to the deflection control circuit 130. The writing mechanism 150 writes a pattern on the target object 101 with the multiple beams 20. The writing control unit 72 controls writing operations of the writing mechanism 150.

Under the control of the writing control unit 72, the writing mechanism 150 performs multiple writing in accordance with the set writing order of each of a plurality of groups each of which is designated by the processing number in multiple writing processing. In other words, the writing control unit 72 performs multiple writing in accordance with the set writing order of each of a plurality of groups each of which is designated by the processing number in multiple writing processing. When performing the multiple writing, with respect to each processing number in multiple writing processing, it is preferable to shift, in the y direction orthogonal to the writing direction (x direction), the irradiation region 34 of the multiple beams 20 by a size less than the pixel size.

According to the first embodiment, when performing multiple writing, the writing mechanism 150 carries out, in each tracking cycle, writing processing indicated by the processing number concerned which is a processing number sequentially changed in multiple writing processing. In a tracking cycle, repeated are a tracking control that makes the irradiation region 34 of the multiple beams 20 follow the movement of the target object 101 placed on the XY stage 105 which moves continuously, and a tracking reset that resets the position of the irradiation region 34 of the multiple beams 20. In performing writing processing indicated by the processing number concerned in each tracking cycle, the writing mechanism 150 writes, with each beam of the multiple beams 20, all the pixels 36 in the same group in any one of sub-irradiation regions 29 being different from each other in the irradiation region 34 of the multiple beams 20 during a tracking control performed in the writing processing indicated by the processing number concerned. Thereby, multiple writing is performed in accordance with the set writing order of each of a plurality of groups each of which is designated by the processing number in the multiple writing processing, during one stage movement in the direction parallel to the writing direction. Hereinafter, it will be specifically described.

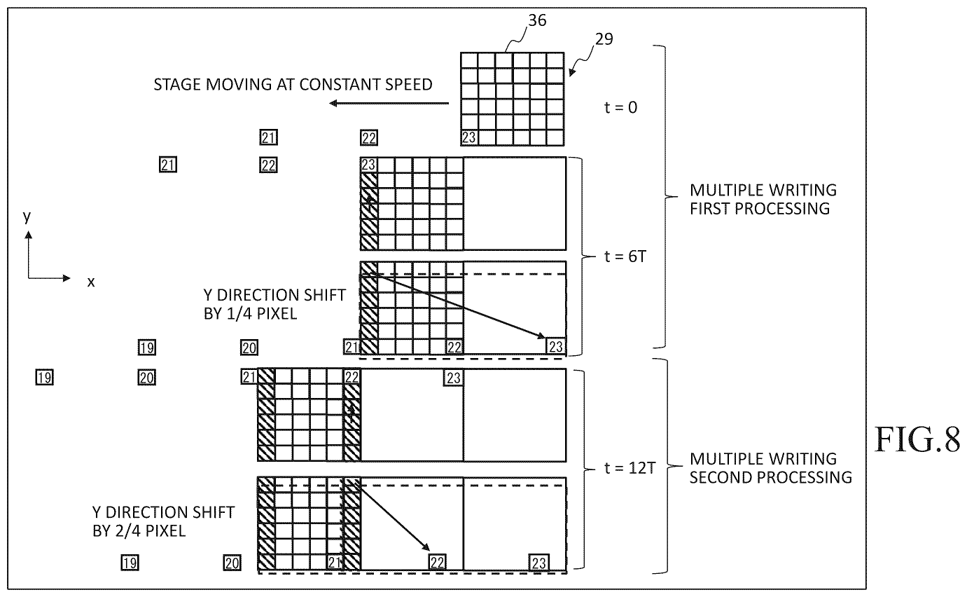

FIG. 8 is an illustration explaining a part of an example of a multiple beam writing operation according to the first embodiment.

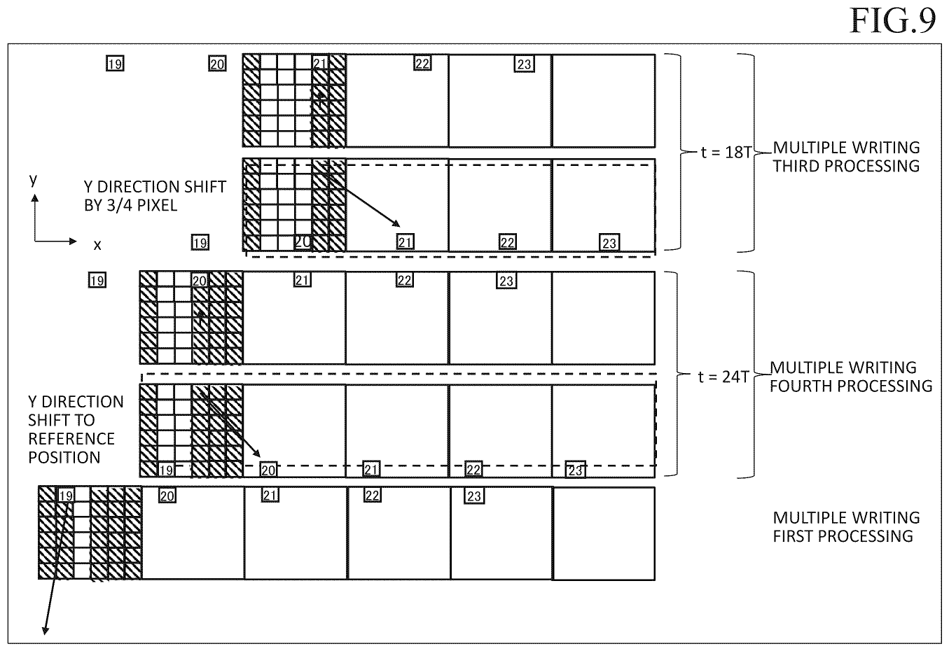

FIG. 9 is an illustration explaining a part of another example of a multiple beam writing operation according to the first embodiment.

In the examples of FIGS. 8 and 9, in each stripe layer, the inside of each sub-irradiation region 29 is written with six different beams. FIG. 8 shows a writing operation where the XY stage 105 continuously moves at the speed at which, while one group (a ⅙ region) in each sub-irradiation region 29 is written, the XY stage 105 moves a distance L of one beam pitch. In the writing operation shown in the example of FIG. 8, for example, while the XY stage 105 moves the distance L of one beam pitch, six different pixels configuring one group in the same sub-irradiation region 29 are written (exposed) by being applied with six shots of multiple beams 20 in a shot cycle T with shifting, in order, the irradiation position (pixel 36) by the sub deflector 209. In order that the relative position between the irradiation region 34 and the target object 101 may not be shifted by the movement of the XY stage 105 while the six pixels are written (exposed), the irradiation region 34 is made to follow the movement of the XY stage 105 by collective deflection of all of the multiple beams 20 by the main deflector 208. In other words, a tracking control is performed. Since one tracking control performs beam irradiation of six shots, a tracking cycle is a time period obtained by adding the settling time of the DAC amplifier to 6T. As the setting time is negligibly short compared to 6T, only 6T is shown in the example of FIG. 8.

In the group shot (tracking control) step (S110), while performing a tracking control, the writing mechanism 150 writes, with each beam of the multiple beams 20, all the pixels 36 in the same group in any one of sub-irradiation regions 29 being different from each other in the irradiation region 34 of the multiple beams 20 during the tracking control. In the multiple writing first processing, the six pixels 36 in the first pixel column from the left in each sub-irradiation region 29 of the group 1 are written from the bottom to the top, for example. FIG. 8 shows the case where the pixel column of the group 1 in a certain sub-irradiation region 29 is written with the beam 23 in the beams having numbers 0 to 23 arrayed in the x direction.

In the tracking reset step (S112), after one tracking cycle 6T is completed, the writing mechanism 150 resets the tracking to return to the last tracking starting position.

In the determining step (S120), the writing control unit 72 determines whether multiple writing of a target stripe has been completed. If the multiple writing of the target stripe has been completed, it proceeds to the determining step (S140). If not completed, it proceeds to the multiple writing processing number switching step (S130).

In the multiple writing processing number switching step (S130), the layer switching processing unit 54 switches, in order, for each tracking reset (tracking cycle), the processing number in multiple writing processing. In other words, the layer switching processing unit 54 switches, for each tracking reset, the last stripe layer having been written to the next stripe layer. In the example of FIG. 8, the multiple writing first processing is switched to the multiple writing second processing. Therefore, the first stripe layer is switched to the second stripe layer.

In the stripe position Y shifting step (S132), the main deflector 208 shifts the position of the irradiation region 34 of the multiple beams 20, by beam deflection, in the y direction by a predetermined shift amount. In the case of performing multiple writing of multiplicity 4, the position is shifted in the y direction by the shift amount of ¼ of the pixel size. Then, it returns to the group shot (tracking control) step (S110). Henceforth, each step from the group shot (tracking control) step (S110) to the stripe position Y shifting step (S132) is repeated until multiple writing of the target stripe region 32 has been completed. In the case of switching from the first writing processing to the second writing processing of multiple writing, the position of the irradiation region 34 in the first stripe layer of the multiple writing first processing is shifted in the y direction by the shift amount of ¼ of the pixel size.

In the case of FIG. 8, since writing to the group 1 of the multiple writing first processing is completed, first, in the next tracking cycle, the sub deflector 209 performs deflection so that the beam writing position may be adjusted (shifted) to write pixels in the sixth pixel column from the left (the first pixel column from the right), which is the first pixel in the group 6 of the multiple writing second processing. Here, the beam writing position is adjusted to the sixth pixel from the left in the first row from the bottom.

While performing a tracking control, the writing mechanism 150 performs writing, as the multiple writing second processing, to all the pixels 36 in the same group in each sub-irradiation region 29 in the stripe region 32 concerned in the second stripe layer during the tracking control. In the multiple writing second processing, the six pixels 36 in the sixth pixel column from the left in each sub-irradiation region 29 of the group 6 are written from the bottom to the top, for example. FIG. 8 shows the case where the pixel column of the group 6 in the sub-irradiation region 29 which has been irradiated with the beam 23 is written with the beam 22 in the beam numbers 0 to 23 arrayed in the x direction.

After completion of writing to the group 6 of the multiple writing second processing, the writing mechanism 150 resets the tracking. The layer switching processing unit 54 switches the multiple writing second processing to the multiple writing third processing. Therefore, the second stripe layer is switched to the third stripe layer. The main deflector 208 shifts the position of the irradiation region 34 of the multiple beams 20, by beam deflection, in the y direction by the shift amount of ¼ of the pixel size. In the case of switching from the second processing to the multiple writing third processing, the irradiation region 34 is shifted from the position in the second stripe layer of the multiple writing second processing, in the y direction by the shift amount of ¼ of the pixel size. Therefore, regarding the position of the first stripe layer as a reference, it is shifted from the reference position by 2/4 of the pixel size.

Since writing to the group 6 of the multiple writing second processing is completed, first, in the next tracking cycle, the sub deflector 209 performs deflection so that the beam writing position may be adjusted (shifted) to write pixels in the fifth pixel column from the left (the second pixel column from the right), which is the first pixel in the group 5 of the multiple writing third processing. Here, the beam writing position is adjusted to the fifth pixel from the left in the first row from the bottom.

While performing a tracking control, the writing mechanism 150 performs writing, as the multiple writing third processing, to all the pixels 36 in the same group in each sub-irradiation region 29 in the stripe region 32 concerned in the third stripe layer during the tracking control. In the multiple writing third processing, the six pixels 36 in the fifth pixel column from the left in each sub-irradiation region 29 of the group 5 are written from the bottom to the top, for example. FIG. 9 shows the case where the pixel column of the group 5 in the sub-irradiation region 29 which has been irradiated with the beams 23 and 22 is written with the beam 21 in the beam numbers 0 to 23 arrayed in the x direction.

After completion of writing to the group 5 of the multiple writing third processing, the writing mechanism 150 resets the tracking. The layer switching processing unit 54 switches the third processing to the multiple writing fourth processing. Therefore, the third stripe layer is switched to the fourth stripe layer. The main deflector 208 shifts the position of the irradiation region 34 of the multiple beams 20, by beam deflection, in the y direction by the shift amount of ¼ of the pixel size. In the case of switching from the third processing to the multiple writing fourth processing, the irradiation region 34 is shifted from the position in the third stripe layer of the multiple writing third processing, in the y direction by the shift amount of ¼ of the pixel size. Therefore, regarding the position of the first stripe layer as a reference, it is shifted from the reference position by ¾ of the pixel size.

Since writing to the group 5 of the multiple writing third processing is completed, first, in the next tracking cycle, the sub deflector 209 performs deflection so that the beam writing position may be adjusted (shifted) to write pixels in the fourth pixel column from the left (the third pixel column from the right), which is the first pixel in the group 4 of the multiple writing fourth processing. Here, the beam writing position is adjusted to the fourth pixel from the left in the first row from the bottom.

While performing a tracking control, the writing mechanism 150 performs writing, as the multiple writing fourth processing, to all the pixels 36 in the same group in each sub-irradiation region 29 in the stripe region 32 concerned in the fourth stripe layer during the tracking control. In the multiple writing fourth processing, the six pixels 36 in the fourth pixel column from the left in each sub-irradiation region 29 of the group 4 are written from the bottom to the top, for example. FIG. 9 shows the case where the pixel column of the group 4 in the sub-irradiation region 29 which has been irradiated with the beams 23, 22, and 21 is written with the beam 20 in the beam numbers 0 to 23 arrayed in the x direction.

After completion of writing to the group 4 of the multiple writing fourth processing, the writing mechanism 150 resets the tracking. The layer switching processing unit 54 switches the fourth processing to the multiple writing first processing. Therefore, the fourth stripe layer is switched to the first stripe layer. The main deflector 208 shifts, by beam deflection, the position of the irradiation region 34 of the multiple beams 20 in the −y direction to return to the reference position of the first stripe layer.

Then, in the multiple writing first processing, the next group, i.e., the group 2, is written. In the next tracking cycle, as the multiple writing second processing, Y deflection shift is performed and the next group, i.e., the group 1, is written. In the next tracking cycle, as the multiple writing third processing, Y deflection shift is performed and the next group, i.e., the group 6, is written. In the next tracking cycle, as the multiple writing fourth processing, Y deflection shift is performed and the next group, i.e., the group 5, is written. In the next tracking cycle, Y deflection shift reset (shifting to return to the reference position) is performed to return to the multiple writing first processing and the next group, i.e., the group 3, is written. Henceforth, similarly, each stripe layer is written in accordance with the set writing order of each of a plurality of groups each of which is designated by the processing number in the multiple writing processing. By repeating this operation, as shown in FIG. 4, the position of the irradiation region 34 moves, such as the irradiation regions 34a to 340, to perform writing to the stripe region 32 concerned.

In the determining step (S140), the writing control unit 72 determines whether multiple writing of all the stripe regions 32 has been completed. If multiple writing of all the stripe regions 32 has been completed, the writing processing is finished. If multiple writing of all the stripe regions 32 has not been completed, after moving the XY stage 105 to a position to be written in the next stripe region 32 which has not been written multiply, it returns to the multiple writing step (S108). Then, the multiple writing step (S108) is repeated until the multiple writing of all the stripe regions 32 has been completed.

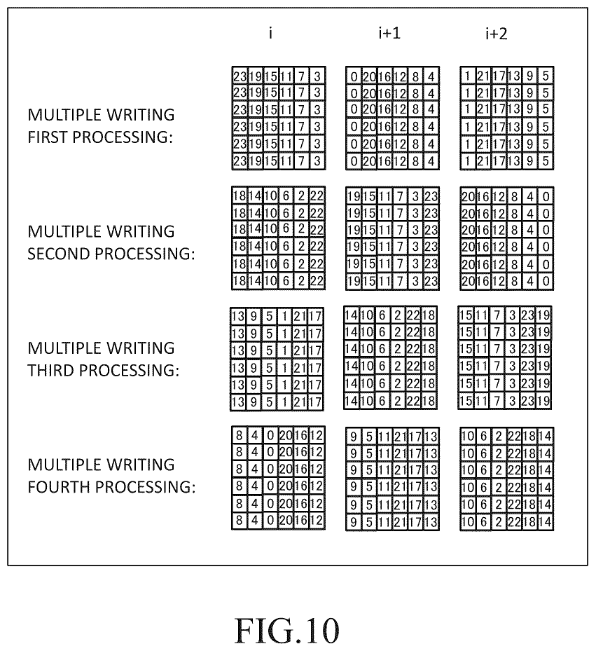

FIG. 10 is an illustration showing an example of numbers of beams having written a sub-irradiation region according to the first embodiment. FIG. 10 shows a part of a result of three sub-irradiation regions 29 arrayed in the x direction in the case of performing writing in accordance with the writing sequence of FIGS. 8 and 9. i indicates an index.

In the i-th x-direction sub-irradiation region 29, in the first processing of multiple writing, writing is performed to the first pixel column from the left with the beam 23, the second one with the beam 19, the third one with the beam 15, the fourth one with the beam 11, the fifth one with the beam 7, and the sixth one with the beam 3. Thus, since the multiplicity is 4, writing is performed with the beams shifted from each other in the x direction by four beams.

In the second processing of multiple writing, writing is performed to the first pixel column from the left with the beam 18, the second one with the beam 14, the third one with the beam 10, the fourth one with the beam 6, the fifth one with the beam 2, and the sixth one with the beam 22.

In the third processing of multiple writing, writing is performed to the first pixel column from the left with the beam 13, the second one with the beam 9, the third one with the beam 5, the fourth one with the beam 1, the fifth one with the beam 21, and the sixth one with the beam 17.

In the fourth processing of multiple writing, writing is performed to the first pixel column from the left with the beam 8, the second one with the beam 4, the third one with the beam 0, the fourth one with the beam 20, the fifth one with the beam 16, and the sixth one with the beam 12.

In respective pixel columns arrayed in the x direction in the (i+1)th x-direction sub-irradiation region 29, in writing processing indicated by a processing number in multiple writing processing, writing is performed with beams which have been individually shifted in the x direction, by one, from the beams applied for the pixel columns arrayed in the x direction in the i-th x-direction sub-irradiation region 29.

In the multiple writing first processing, writing is performed to the first pixel column from the left with the beam 0, the second one with the beam 20, the third one with the beam 16, the fourth one with the beam 12, the fifth one with the beam 8, and the sixth one with the beam 4.

In the multiple writing second processing, writing is performed to the first pixel column from the left with the beam 19, the second one with the beam 15, the third one with the beam 11, the fourth one with the beam 7, the fifth one with the beam 3, and the sixth one with the beam 23.

In the multiple writing third processing, writing is performed to the first pixel column from the left with the beam 14, the second one with the beam 10, the third one with the beam 6, the fourth one with the beam 2, the fifth one with the beam 22, and the sixth one with the beam 18.

In the multiple writing fourth processing, writing is performed to the first pixel column from the left with the beam 9, the second one with the beam 5, the third one with the beam 1, the fourth one with the beam 21, the fifth one with the beam 17, and the sixth one with the beam 13.

Similarly, in respective pixel columns arrayed in the x direction in the (i+2)th x-direction sub-irradiation region 29, in writing processing indicated by a processing number in multiple writing processing, writing is performed with beams which have been individually shifted in the x direction by one from the beams used in the pixel columns arrayed in the x direction in the (i+1)th x-direction sub-irradiation region 29.

In the multiple writing first processing, writing is performed to the first pixel column from the left with the beam 1, the second one with the beam 21, the third one with the beam 17, the fourth one with the beam 13, the fifth one with the beam 9, and the sixth one with the beam 5.

In the multiple writing second processing, writing is performed to the first pixel column from the left with the beam 20, the second one with the beam 16, the third one with the beam 12, the fourth one with the beam 8, the fifth one with the beam 4, and the sixth one with the beam 0.

In the multiple writing third processing, writing is performed to the first pixel column from the left with the beam 15, the second one with the beam 11, the third one with the beam 7, the fourth one with the beam 3, the fifth one with the beam 23, and the sixth one with the beam 19.

In the multiple writing fourth processing, writing is performed to the first pixel column from the left with the beam 10, the second one with the beam 6, the third one with the beam 2, the fourth one with the beam 22, the fifth one with the beam 18, and the sixth one with the beam 14.

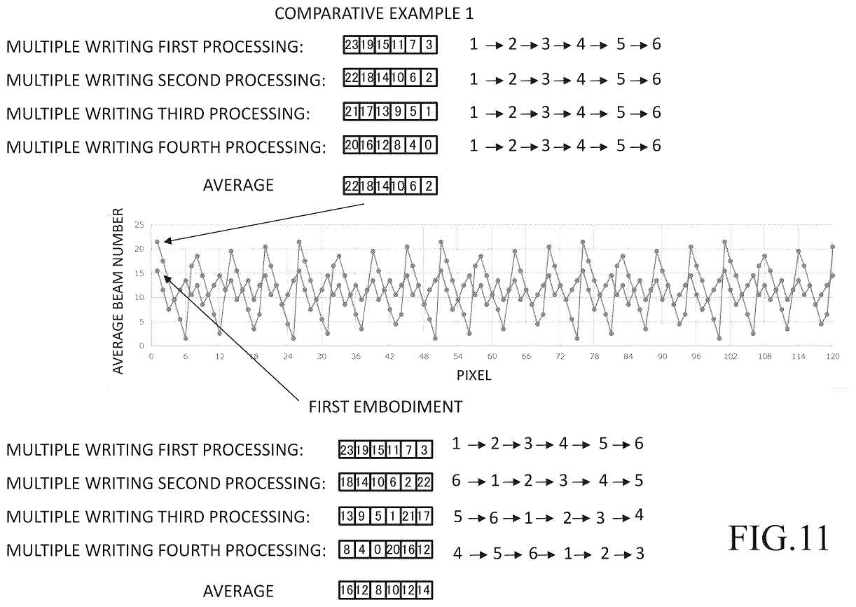

FIG. 11 is an illustration showing an example of an average beam number of a plurality of beams which write respective positions according to the first embodiment and a comparative example 1. In FIG. 11, the ordinate axis represents an average beam number, and the abscissa axis represents an x-direction position of a pixel. The comparative example 1 shows the case where, in writing processing indicated by a processing number in multiple writing processing, the writing orders of a plurality of groups are set to be the same as each other. Other writing sequences are the same as those of the first embodiment.

As shown in FIG. 11, the average beam number of pixel columns of the sub-irradiation region 29 whose multiple writing first processing is written with the beam 23 is 22 in the comparative example 1, whereas 16 according to the first embodiment. Furthermore, the average beam number of pixel columns of the sub-irradiation region 29 whose multiple writing first processing is written with the beam 19 is 18 in the comparative example 1, whereas 12 according to the first embodiment. Furthermore, the average beam number of pixel columns of the sub-irradiation region 29 whose multiple writing first processing is written with the beam 15 is 14 in the comparative example 1, whereas 8 according to the first embodiment. Furthermore, the average beam number of pixel columns of the sub-irradiation region 29 whose multiple writing first processing is written with the beam 11 is 10 in the comparative example 1, and is also 10 according to the first embodiment. Furthermore, the average beam number of pixel columns of the sub-irradiation region 29 whose multiple writing first processing is written with the beam 7 is 6 in the comparative example 1, whereas 12 according to the first embodiment. Furthermore, the average beam number of pixel columns of the sub-irradiation region 29 whose multiple writing first processing is written with the beam 3 is 2 in the comparative example 1, whereas 14 according to the first embodiment.

As described above, in the comparative example 1, the average beam numbers are scattered between 2 and 22, for example, whereas kept in the range between 8 and 16, for example, in the first embodiment. In other words, in the comparative example 1, there are a lot of pixel columns written only with a plurality of beams located at a partial and biased region in the beam array region. By contrast, in the first embodiment, writing can be performed with a plurality of beams located all over the beam array region. The same can be applied to the sub-irradiation regions 29 arrayed in the x direction. Therefore, according to the first embodiment, compared with the comparative example 1, it is possible to increase the averaging effect with respect to position deviation due to distortion of a beam array shape.

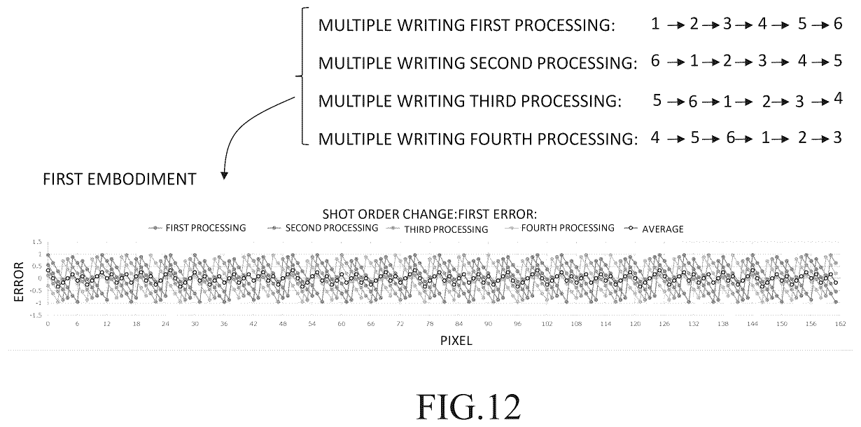

FIG. 12 is an illustration showing an example of a relationship between a position deviation amount and a pixel position, in writing processing indicated by each processing number in multiple writing processing according to the first embodiment.

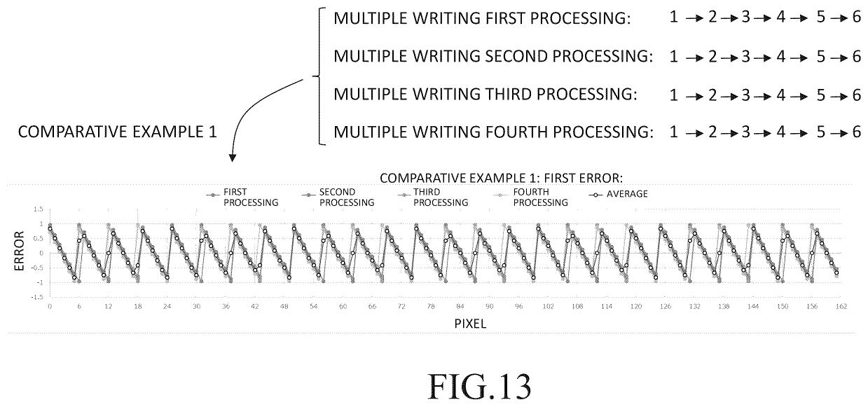

FIG. 13 is an illustration showing an example of a relationship between a position deviation amount and a pixel position, in writing processing indicated by each processing number in multiple writing processing according to the comparative example 1 of the first embodiment.

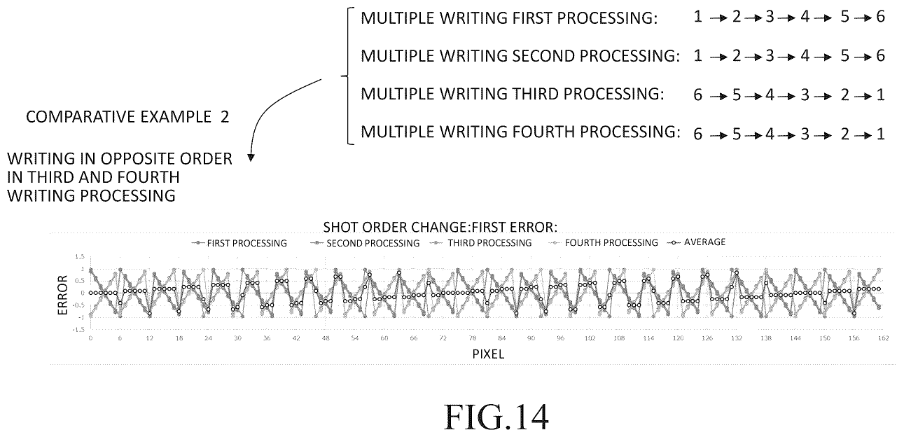

FIG. 14 is an illustration showing an example of a relationship between a position deviation amount and a pixel position, in writing processing indicated by each processing number in multiple writing processing according to a comparative example 2 of the first embodiment.

In FIGS. 12 to 14, the ordinate axis represents an amount of position deviation (error), and the abscissa axis represents a pixel position in the x direction. The examples of FIGS. 12 to 14 show an amount of position deviation generated in each pixel on the assumption that the position deviation amount (error) at the center position of a design beam array shape is 0 (zero), the position deviation amount at the −x direction end portion is-1, and the position deviation amount at the x direction end portion is +1. Furthermore, FIGS. 12 to 14 show overlapped position deviation amounts at each pixel position in writing processing indicated by respective processing numbers of multiple writing processing.

The comparative example 1 shows the case where writing is performed in accordance with the writing sequence explained with reference to FIG. 11. The comparative example 2 shows the case where, in the first and second writing processing, each group is written in the same writing order, and in the third and fourth writing processing, each group is written in the opposite writing order to that of the first and second writing processing.

In the comparative example 1, as shown in FIG. 13, since the position deviation amount changes in a similar manner in each of the writing processing of multiple writing, it turns out that the position deviation amount is not cancelled out even when multiple writing is performed.

In the comparative example 2, as shown in FIG. 14, although the position deviation amount is cancelled out in some of the sub-irradiation regions 29, since the relation of the position deviation amount shifts gradually in other sub-irradiation regions 29, the averaging effect with respect to the position deviation amount is reduced.

In contrast, in the first embodiment shown in FIG. 12, it turns out that the position deviation amount is equalized (averaged) in all the sub-irradiation regions 29.

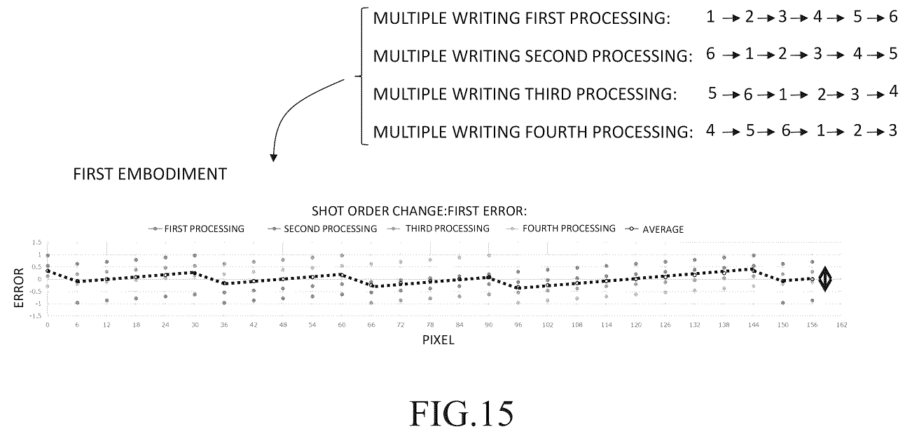

FIG. 15 is an illustration showing an example of a relation between an average error value and a pixel position in multiple writing processing to a pixel at the same position in each sub-irradiation region according to the first embodiment.

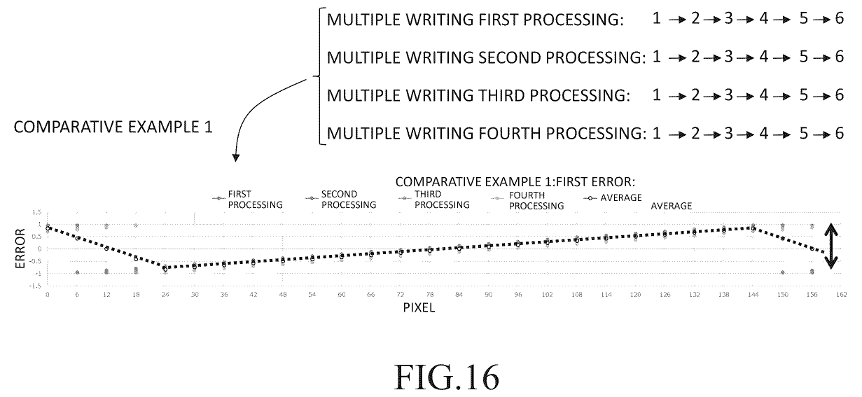

FIG. 16 is an illustration showing an example of a relation between an average error value and a pixel position in multiple writing processing to a pixel at the same position in each sub-irradiation region according to the comparative example 1 of the first embodiment.

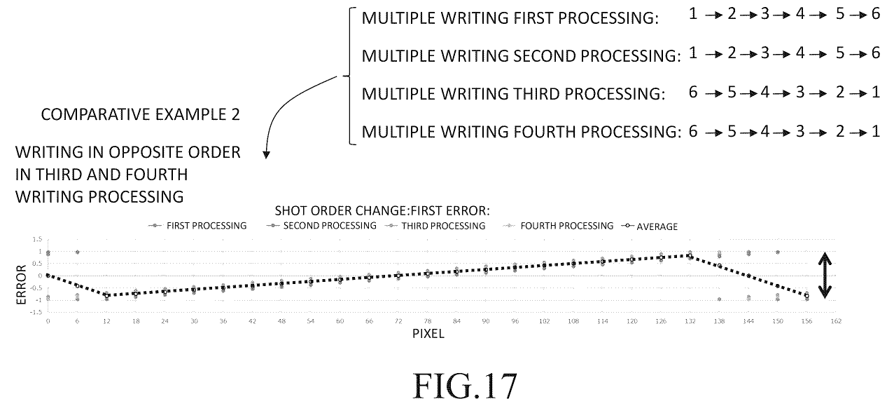

FIG. 17 is an illustration showing an example of a relation between an average error value and a pixel position in multiple writing processing to a pixel at the same position in each sub-irradiation region according to the comparative example 2 of the first embodiment.

In FIGS. 15 to 17, the ordinate axis represents an average position deviation amount (average error value), and the abscissa axis represents a pixel position in the x direction. The average error value denotes an average of error values in writing processing indicated by respective processing numbers in the case of performing multiple writing processing to the pixel concerned. In the examples of FIGS. 15 to 17, there are shown graphs each with respect to the first pixel from the left in the first row from the bottom in each of the sub-irradiation regions 29 arranged in the x direction.

In the comparative example 1, as shown in FIG. 16, as the sub-irradiation region 29 of interest is shifted in the x direction, the average error value is displaced to the negative side in the range between −1 to +1, reversed on the way, and then, displaced to the positive side in the range between −1 to +1. It indicates that averaging of the position deviation amount of the pixel concerned has not been successfully performed.

In the comparative example 2, as shown in FIG. 17, as the sub-irradiation region 29 of interest is shifted in the x direction, the average error value is displaced to the negative side in the range between −1 to +1, reversed on the way, and then, displaced to the positive side in the range between −1 to +1. It indicates that averaging of the position deviation amount of the pixel concerned has not been successfully performed.

In contrast, in the first embodiment shown in FIG. 15, although the average error value is displaced with the sub-irradiation region 29 of interest being shifted in the x direction, its range is kept between −0.4 to +0.4. Therefore, it turn out that, in all the sub-irradiation regions 29, the averaging effect is large with respect to the position deviation amount of the pixel concerned.

As described above, according to the first embodiment, pattern position deviation due to distortion of a beam array shape can be reduced. Furthermore, by executing position deviation in the y direction by a size less than the pixel size, the averaging effect with respect to position deviation at the pixel boundary can be increased.

### Second Embodiment

Although the first embodiment describes multiple writing performed in the same pass, it is not limited thereto. A second embodiment describes multiple writing performed by moving the XY stage 105 in the same stripe region 32 a plurality of times.

The configuration of the writing apparatus 100 in the second embodiment may be the same as that of FIG. 1. The contents of the second embodiment are the same as those of the first embodiment except for what is particularly described below.

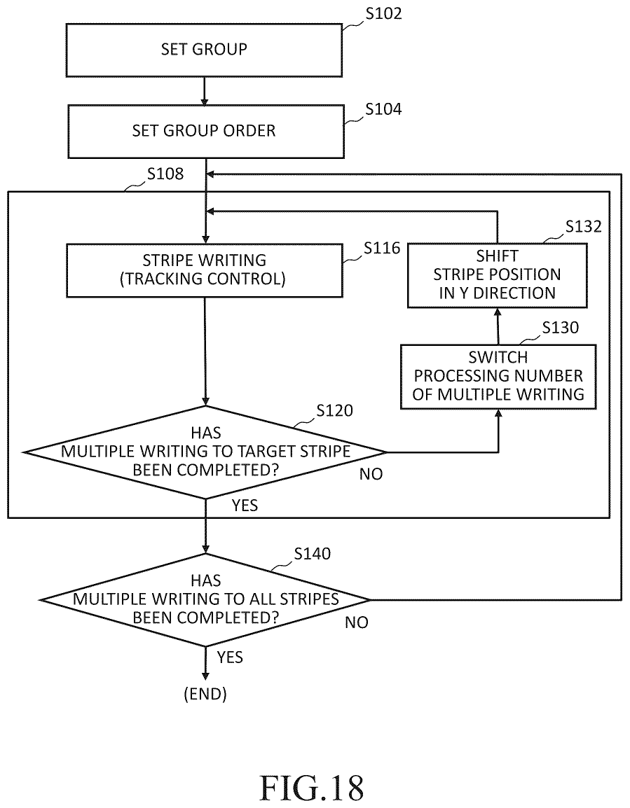

FIG. 18 is a flowchart showing an example of main steps of a writing method according to the second embodiment. In FIG. 18, the writing method of the second embodiment executes a series of steps: the group setting step (S102), the group order setting step (S104), the multiple writing step (S108), and the determining step (S140). The multiple writing step (S108) executes, as internal steps, a stripe writing (tracking control) step (S116), the determining step (S120), the multiple writing processing number switching step (S130), and the stripe position Y shifting step (S132).

The contents of the group setting step (S102), and the group order setting step (S104) are the same as those of the first embodiment.

The multiple writing step (S108) of the second embodiment is the same as that of the first embodiment in that, first, the writing data processing unit 70 generates irradiation time data for each pixel. Furthermore, for example, in writing processing of multiplicity 4, in each writing processing indicated by each processing number, a beam of ¼ dose of a necessary dose, for example, is applied to a target pixel. Irradiation time data is rearranged in the order of shots in accordance with a preset writing sequence.

The irradiation time data is stored in the storage device 142. The transmission processing unit 74 transmits the irradiation time data in the order of shots to the deflection control circuit 130. Under the control of the writing control unit 72, the writing mechanism 150 performs multiple writing in accordance with the set writing order of each of a plurality of groups each of which is designated by the processing number in the multiple writing processing.

According to the second embodiment, one writing processing of multiple writing processing is performed during one stage movement in the direction parallel to the writing direction. For example, in writing processing of multiplicity 4, four stage movements in the direction parallel to the writing direction are performed per one stripe region 32. Similarly to the first embodiment, when performing multiple writing, with respect to each processing number in multiple writing processing, it is preferable to shift, in the y direction orthogonal to the writing direction (x direction), the irradiation region 34 of the multiple beams 20 by a size less than the pixel size. Hereinafter, it will be specifically described.

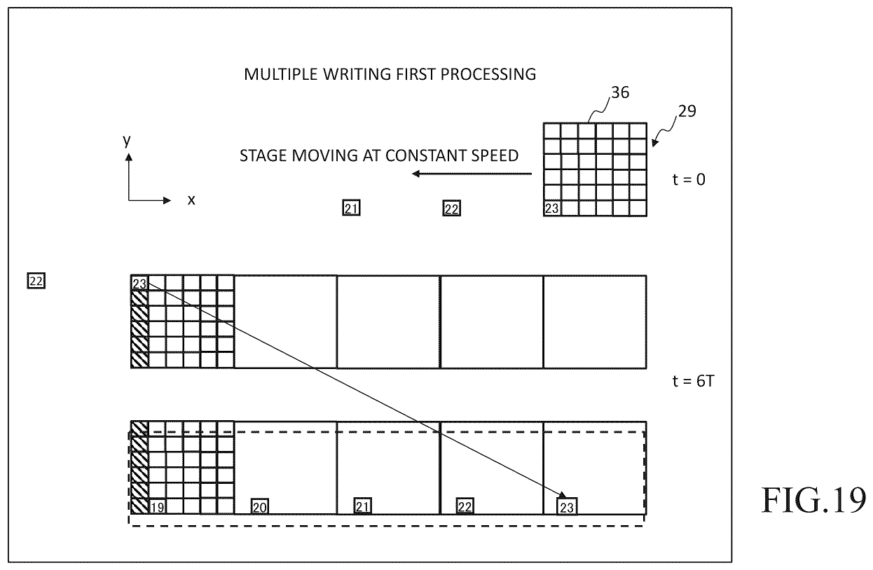

FIG. 19 is an illustration explaining a part of an example of a multiple beam writing operation according to the second embodiment.

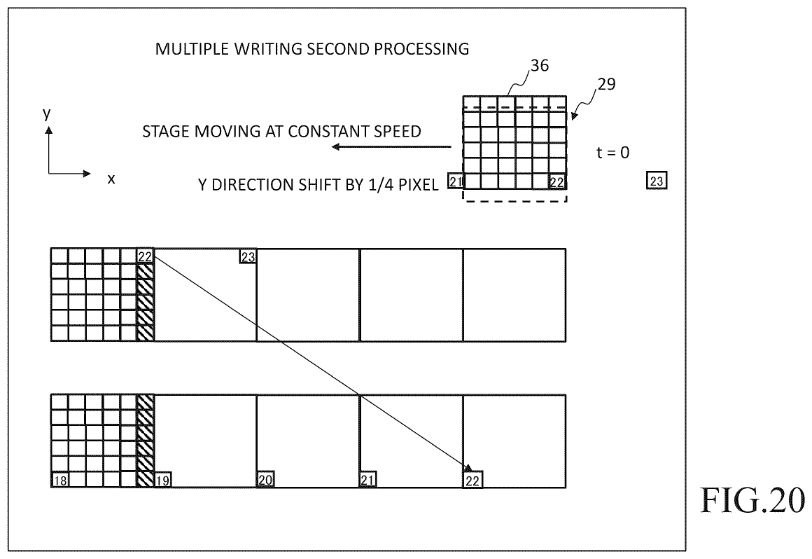

FIG. 20 is an illustration explaining a part of another example of a multiple beam writing operation according to the second embodiment.

In the examples of FIGS. 19 and 20, similarly to the first embodiment, in each stripe layer, the inside of each sub-irradiation region 29 is written with six different beams. FIG. 19 shows a writing operation where the XY stage 105 continuously moves at the speed at which, while one group (a ⅙ region) in each sub-irradiation region 29 is written, the XY stage 105 moves a distance L of four beam pitches. In the writing operation shown in the example of FIG. 19, for example, while the XY stage 105 moves the distance L of four beam pitches, six different pixels configuring one group in the same sub-irradiation region 29 are written (exposed) by being applied with six shots of multiple beams 20 in a shot cycle T with shifting, in order, the irradiation position (pixel 36) by the sub deflector 209. In order that the relative position between the irradiation region 34 and the target object 101 may not be shifted by the movement of the XY stage 105 while the six pixels are written (exposed), the irradiation region 34 is made to follow the movement of the XY stage 105 by collective deflection of all of the multiple beams 20 by the main deflector 208. In other words, a tracking control is performed. Since one tracking control performs beam irradiation of six shots, a tracking cycle is a time period obtained by adding the settling time of the DAC amplifier to 6T. As the setting time is negligibly short compared to 6T, only 6T is shown in the example of FIG. 19.

In the stripe writing (tracking control) step (S116), while performing a tracking control, the writing mechanism 150 writes, with each beam of the multiple beams 20, all the pixels 36 in the same group in any one of sub-irradiation regions 29 being different from each other in the irradiation region 34 of the multiple beams 20 during the tracking control.

In the multiple writing first processing, the six pixels 36 in the first pixel column from the left in each sub-irradiation region 29 of the group 1 are written from the bottom to the top, for example. FIG. 19 shows the case where the pixel column of the group 1 in a certain sub-irradiation region 29 is written with the beam 23 in the beams having numbers 0 to 23 arrayed in the x direction.

After one tracking cycle 6T is completed, the writing mechanism 150 resets the tracking to return to the last tracking starting position. Since writing to the group 1 of the multiple writing first processing is completed, first, in the next tracking cycle, the sub deflector 209 performs deflection so that the beam writing position may be adjusted (shifted) to write pixels in the second pixel column from the left, which is the first pixel in the group 2 of the next multiple writing first processing. Here, the beam writing position is adjusted to the second pixel from the left in the first row from the bottom.

While performing a tracking control, the writing mechanism 150 executes writing to the group 2 in the multiple writing first processing. Henceforth, in the same way, while repeating a tracking control and a tracking reset, writing is performed in the order of the groups 3, 4, 5, and 6. During one movement of the XY stage 105 in the direction parallel to the writing direction, the multiple writing first processing is performed to the whole stripe region 32.

In the determining step (S120), the writing control unit 72 determines whether multiple writing of a target stripe has been completed. If the multiple writing of the target stripe has been completed, it proceeds to the determining step (S140). If not completed, it proceeds to the multiple writing processing number switching step (S130).

In the multiple writing processing number switching step (S130), the layer switching processing unit 54 switches, in order, for each writing to each stripe region, the processing number in multiple writing processing. In other words, the layer switching processing unit 54 switches, for each writing to each stripe region, the last stripe layer having been written to the next stripe layer. In the example of FIG. 19, the multiple writing first processing is switched to the multiple writing second processing. Therefore, the first stripe layer is switched to the second stripe layer.

In the stripe position Y shifting step (S132), the main deflector 208 shifts the position of the irradiation region 34 of the multiple beams 20, by beam deflection, in the y direction by a predetermined shift amount. In the case of performing multiple writing of multiplicity 4, the position is shifted in the y direction by the shift amount of ¼ of the pixel size. Then, it returns to the stripe writing (tracking control) step (S116). Henceforth, each step from the stripe writing (tracking control) step (S116) to the stripe position Y shifting step (S132) is repeated until multiple writing of the target stripe region 32 has been completed. In the case of switching from the first writing processing to the second writing processing of multiple writing, the position of the irradiation region 34 in the first stripe layer of the multiple writing first processing is shifted in the y direction by the shift amount of ¼ of the pixel size. Then, writing starts from the first position of the target stripe region 32.

In the multiple writing second processing, the six pixels 36 in the sixth pixel column from the left in each sub-irradiation region 29 of the group 6 are written from the bottom to the top, for example. FIG. 20 shows the case where the pixel column of the group 6 in a certain sub-irradiation region 29 is written with the beam 22 in the beams having numbers 0 to 23 arrayed in the x direction.

After one tracking cycle 6T is completed, the writing mechanism 150 resets the tracking to return to the last tracking starting position. Since writing to the group 6 of the multiple writing second processing is completed, first, in the next tracking cycle, the sub deflector 209 performs deflection so that the beam writing position may be adjusted (shifted) to write pixels in the first pixel column from the left, which is the first pixel in the group 1 of the multiple writing second processing. Here, the beam writing position is adjusted to the first pixel from the left in the first row from the bottom.

While performing a tracking control, the writing mechanism 150 performs writing to the group 1 of the multiple writing second processing. Henceforth, in the same way, while repeating a tracking control and a tracking reset, writing is performed in the order of the groups 2, 3, 4, and 5. During one movement of the XY stage 105 in the direction parallel to the writing direction, the multiple writing second processing is performed to the whole stripe region 32.

After the multiple writing second processing is completed, the position of the irradiation region 34 in the second stripe layer of the multiple writing second processing is shifted in the y direction by the shift amount of ¼ of the pixel size. Then, writing starts from the first position of the target stripe region 32.

In the multiple writing third processing, while repeating a tracking control and a tracking reset, writing is performed in the order of the groups 5, 6, 1, 2, 3 and 4. During one movement of the XY stage 105 in the direction parallel to the writing direction, the multiple writing third processing is performed to the whole stripe region 32.

After the multiple writing third processing is completed, the position of the irradiation region 34 in the second stripe layer of the multiple writing third processing is shifted in the y direction by the shift amount of ¼ of the pixel size. Then, writing starts from the first position of the target stripe region 32.

In the multiple writing fourth processing, while repeating a tracking control and a tracking reset, writing is performed in the order of the groups 4, 5, 6, 1, 2, and 3. During one movement of the XY stage 105 in the direction parallel to the writing direction, the multiple writing fourth processing is performed to the whole stripe region 32.

After completing writing up to the multiple writing fourth processing, it proceeds to the determining step (S140).

In the determining step (S140), the writing control unit 72 determines whether multiple writing of all the stripe regions 32 has been completed. If multiple writing of all the stripe regions 32 has been completed, the writing processing is finished. If multiple writing of all the stripe regions 32 has not been completed, after moving the XY stage 105 to a position to be written in the next stripe region 32 which has not been written multiply, it returns to the multiple writing step (S108). Then, the multiple writing step (S108) is repeated until the multiple writing of all the stripe regions 32 has been completed.

By performing the operations described above, examples of beam numbers with which the sub-irradiation region is written according to the second embodiment can be the same as those of FIG. 10. Therefore, the same effect as the first embodiment can be acquired.

Embodiments have been explained referring to specific examples described above. However, the present invention is not limited to these specific examples.

The Embodiments described above show the case where each group is composed of a plurality of pixels 36, for example, but it is not limited thereto. Each group may be composed of one pixel 36, for example. That is to say, it is also preferable to repeat performing writing to only one pixel 36 during one tracking control, and then performing tracking reset.

In that case, the group order setting unit 52 sets the writing order of a plurality of pixels 36, located in each of a plurality of sub-irradiation regions 29, designated by the processing number in multiple writing processing, so that the writing order of the plurality of pixels 36 in each of the plurality of sub-irradiation regions 29 may be different from each other depending on the processing number in multiple writing processing.

The writing mechanism 150 performs multiple writing in accordance with the set writing order of each of a plurality of beam irradiation unit regions in each of a plurality of pitch cell regions each designated by the processing number in multiple writing processing.

In doing the above, as operations according to the second embodiment, writing processing indicated by the processing number concerned, which is a processing number sequentially changed in multiple writing processing, is performed for each tracking cycle of repeating a tracking control and a tracking reset. In that case, writing is performed, with each beam of the multiple beams 20, to the same pixel 36 in any one of sub-irradiation regions 29 being different from each other in the irradiation region 34 of the multiple beams 20 during a tracking control performed in the writing processing indicated by the processing number concerned. By this operation, multiple writing is performed in accordance with the set writing order of a plurality of pixels 36 in each of a plurality of sub-irradiation regions 29, designated by the processing number in the multiple writing processing during one stage movement in the direction parallel to the writing direction. When switching the processing number in multiple writing processing, similarly to the first embodiment, it is preferable to perform the Y direction shift by a size less than the pixel size as described above.

As operations according to the second embodiment, the writing order of a plurality of pixels 36 in each sub-irradiation region 29 in the target stripe region 32 can be varied for each pass. When switching the processing number in multiple writing processing, similarly to the first embodiment, it is preferable to perform the Y direction shift by a size less than the pixel size as described above.

Functions of processing described in each embodiment may be executed by a computer. A program for causing a computer to implement such functions of processing may be stored in a non-transitory tangible computer-readable storage medium such as a magnetic disk drive.

While the apparatus configuration, control method, and the like not directly necessary for explaining the present invention are not described, some or all of them can be appropriately selected and used on a case-by-case basis when needed. For example, although description of the configuration of the control unit for controlling the writing apparatus 100 is omitted, it should be understood that some or all of the configuration of the control unit can be selected and used appropriately when necessary.

Furthermore, any multiple charged particle beam writing apparatus, multiple charged particle beam writing method, and program that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multiple charged particle beam writing method comprising:
setting a plurality of groups each composed of a plurality of beam irradiation unit regions located in each of a plurality of pitch cell regions being a mesh shape obtained by dividing a writing region of a substrate by a beam pitch size between beams of multiple charged particle beams on the substrate;
setting a writing order of each of the plurality of groups each designated by each processing number indicating a processing order of multiple writing processing such that the writing order of the each of the plurality of groups is different from each other depending on the each processing number; and
performing multiple writing in accordance with a set writing order of the each of the plurality of groups each designated by the each processing number in the multiple writing processing.

2. The method according to claim 1, wherein, in a case of performing the multiple writing, in each tracking cycle of repeating a tracking control that makes an irradiation region of the multiple charged particle beams follow a movement of the substrate placed on a stage moving continuously and a tracking reset that resets a position of the irradiation region of the multiple charged particle beams, while performing writing processing indicated by a processing number concerned having been sequentially changed in the multiple writing processing, the multiple writing is performed in accordance with the set writing order of the each of the plurality of groups each designated by the each processing number in the multiple writing processing during one movement of the stage in a direction parallel to a writing direction, by writing, with each beam of multiple charged particle beams, all of the plurality of beam irradiation unit regions in a same group in any one of the plurality of pitch cell regions being different from each other in the irradiation region of the multiple charged particle beams during the tracking control performed in the writing processing indicated by the processing number concerned.

3. The method according to claim 1, wherein, with respect to the each processing number in the multiple writing processing, the writing order of the each of the plurality of groups is sequentially shifted.

4. The method according to claim 1, wherein, with respect to the each processing number in the multiple writing processing, the irradiation region of the multiple charged particle beams is shifted in a direction orthogonal to a writing direction by a size less than a size of each of the plurality of beam irradiation unit regions.

5. A non-transitory computer-readable storage medium storing a program for causing a computer to execute processing comprising:
setting a plurality of groups each composed of a plurality of beam irradiation unit regions located in each of a plurality of pitch cell regions being a mesh shape obtained by dividing a writing region of a substrate by a beam pitch size between beams of multiple charged particle beams on the substrate;
setting a writing order of each of the plurality of groups each designated by each processing number indicating a processing order of multiple writing processing such that the writing order of the each of the plurality of groups is different from each other depending on the each processing number;
storing, in a storage device, a set writing order of the each of the plurality of groups each designated by the each processing number in the multiple writing processing; and
reading the set writing order of the each of the plurality of groups each designated by the each processing number in the multiple writing processing from the storage device, and performing multiple writing in accordance with the set writing order of the each of the plurality of groups each designated by the each processing number in the multiple writing processing.

6. A multiple charged particle beam writing apparatus comprising:
a group setting circuit configured to set a plurality of groups each composed of a plurality of beam irradiation unit regions located in each of a plurality of pitch cell regions being a mesh shape obtained by dividing a writing region of a substrate by a beam pitch size between beams of multiple charged particle beams on the substrate;
a group order setting circuit configured to set a writing order of each of the plurality of groups each designated by each processing number indicating a processing order of multiple writing processing such that the writing order of the each of the plurality of groups is different from each other depending on the each processing number; and
a writing control circuit configured to perform multiple writing in accordance with a set writing order of the each of the plurality of groups each designated by the each processing number in the multiple writing processing.

7. A multiple charged particle beam writing method comprising:
setting a writing order of a plurality of beam irradiation unit regions in each of a plurality of pitch cell regions each designated by each processing number indicating a processing order of multiple writing processing, where the plurality of pitch cell regions have been obtained by dividing, to be a mesh shape, a writing region of a substrate by a beam pitch size between beams of multiple charged particle beams on the substrate such that the writing order of the plurality of beam irradiation unit regions in the each of the plurality of pitch cell regions is different from each other depending on the each processing number; and
performing multiple writing, in each tracking cycle of repeating a tracking control that makes an irradiation region of the multiple charged particle beams follow a movement of the substrate placed on a stage moving continuously and a tracking reset that resets a position of the irradiation region of the multiple charged particle beams, while performing writing processing indicated by a processing number concerned having been sequentially changed in the multiple writing processing, in accordance with a set writing order of the plurality of beam irradiation unit regions in the each of the plurality of pitch cell regions each designated by the each processing number in the multiple writing processing during one movement of the stage in a direction parallel to a writing direction, by writing, with each beam of the multiple charged particle beams, a same beam irradiation unit region in any one of the plurality of pitch cell regions being different from each other in the irradiation region of the multiple charged particle beams during the tracking control performed in the writing processing indicated by the processing number concerned.
